(19) United States
(12) Patent Application Publication
(10) Pub. No.: US 2024/0159590 A1
(43) Pub. Date: May 16, 2024

(54) FOCUS RING INSPECTION DEVICE AND FOCUS RING INSPECTION METHOD

(71) Applicant: SEMES CO., LTD., Cheonan-si (KR)

(72) Inventors: Jin Il SUNG, Cheonan-si (KR); Dong Mok LEE, Cheonan-si (KR); Sun Il KIM, Cheonan-si (KR); Ki Ryong LEE, Cheonan-si (KR)

(73) Assignee: SEMES CO., LTD., Cheonan-si (KR)

(21) Appl. No.: 18/507,065

(22) Filed: Nov. 12, 2023

(30) Foreign Application Priority Data
Nov. 11, 2022 (KR) 10-2022-0150708

(51) Int. Cl. G01J 5/00; H01J 37/32

(52) U.S. Cl. CPC G01J 5/0003; H01J 37/32642; G01J 2005/0077

(57) ABSTRACT

Proposed is an inspection technology for inspecting a focus ring. A device and a method for inspecting the focus ring including a heat transfer member are proposed. The inspection device may include a housing configured to provide inspection space of the focus ring, with a predetermined area of an upper wall of the housing being formed of a transparent material, a hot plate provided in the housing and configured to heat treat the focus ring while the hot plate supports the focus ring, and an inspection unit configured to inspect a connection state between the focus ring and the heat transfer member by obtaining a thermal image of the focus ring after the focus ring is completely heat treated.

### CROSS REFERENCE TO RELATED APPLICATION

The present application claims priority to Korean Patent Application No. 10-2022-0150708, filed Nov. 11, 2022, the entire contents of which are incorporated by reference herein for all purposes.

### BACKGROUND OF THE INVENTION

### 1. Field of the Invention

The present disclosure relates to an inspection device and an inspection method in which a focus ring provided to surround a substrate to focus plasma onto the substrate can be inspected.

### 2. Description of the Related Art

Generally, a process for manufacturing a semiconductor device includes a deposition process for forming a film on a semiconductor wafer (hereinafter referred to as a substrate), a chemical/mechanical polishing process for planarizing the film, a photolithography process for forming a photoresist pattern on the film, an etching process for forming a film into a pattern having electrical characteristics by using the photoresist pattern, an ion implantation process for implanting specific ions into a predetermined region of the substrate, and a cleaning process for removing impurities on the substrate, and an inspection process for inspecting the surface of the substrate on which the film or pattern is formed.

The etching process is a process for removing an exposed area of a photoresist pattern formed on a substrate by a photolithography process. In general, the type of etching process may be divided into a dry etching process and a wet etching process.

In the dry etching process, high-frequency power is applied to an upper electrode and a lower electrode installed by being spaced by a predetermined interval apart from each other in sealed inner space in which an etching process is performed so that an electric field is formed, and the electric field is applied to reaction gas supplied into the sealed space to activate the reaction gas so that the reaction gas is turned into plasma, and then ions in the plasma etch a substrate located on the lower electrode.

In this case, it is required to form the plasma uniformly over the entire upper surface of the substrate. A focus ring is provided to uniformly form plasma over the entire upper surface of the substrate.

The focus ring is installed to surround the edge of an electrostatic chuck (ESC) and a substrate disposed on the lower electrode. An electric field is formed on the upper side of the electrostatic chuck by applying high-frequency power thereto, and the focus ring more greatly expands an area in which the electric field is formed than an area which the substrate is located. Accordingly, the substrate is located at the center of an area which plasma is formed, and thus the substrate can be uniformly etched.

In plasma processing, since the substrate and the focus ring are directly exposed to plasma, temperatures of the substrate and the focus ring rise as an etching process progresses. Since the temperature rise of the substrate and focus ring affects the etching characteristics of the substrate, the temperature of the electrostatic chuck supporting the substrate is controlled so that the temperature of the substrate and the temperature of the focus ring are controlled. However, in a case in which heat transfer efficiency between the electrostatic chuck and the focus ring is low, it is difficult to control the temperature of the focus ring. Therefore, a technique for improving the heat transfer efficiency by placing a heat transfer member such as silicone rubber between the electrostatic chuck and the focus ring to increase adhesion therebetween has been proposed.

When the heat transfer member is disposed between the electrostatic chuck and the focus ring, a temperature gradient in the focus ring that is heated by plasma treatment varies depending on an adhesion state between the focus ring and the heat transfer member. Since the temperature gradient in the focus ring affects the etching rate of a wafer and the line width of a pattern formed on the wafer, a system that can independently inspect the temperature gradient in the focus ring and the adhesion state between the focus ring and the heat transfer member is required.

### SUMMARY OF THE INVENTION

Accordingly, the present disclosure has been made keeping in mind the above problems occurring in the related art, and the present disclosure is intended to propose a focus ring inspection system that can independently inspect the state of a focus ring provided to cover the edge of a substrate and an electrostatic chuck for uniform plasma treatment.

In addition, the present disclosure is intended to propose a focus ring inspection system that can measure temperature distribution in the focus ring.

In addition, the present disclosure is intended to propose an inspection system that can inspect the adhesion state of a heat transfer member attached to a lower surface of the focus ring in order to improve heat transfer efficiency for the focus ring on the basis of heat distribution in the focus ring.

Objectives to be achieved by the present disclosure are not limited to the above-mentioned objectives, and objectives not mentioned can be clearly understood by those skilled in the art from this specification and the accompanying drawings.

In order to achieve the above objectives, according to one embodiment of the present disclosure, there is provided an inspection device for inspecting a focus ring including a heat transfer member. The inspection device includes: a housing configured to provide inspection space of the focus ring, with a predetermined area of an upper wall of the housing being formed of a transparent material; a hot plate provided in the inspection space and configured to heat treat the focus ring while the hot plate supports the focus ring; and an inspection unit configured to inspect a connection state between the focus ring and the heat transfer member by obtaining a thermal image of the focus ring after the focus ring is completely heat treated.

According to another embodiment of the present disclosure, there is provided an inspection method including: introducing a focus ring having a heat transfer member attached thereto into inspection space; heating the focus ring to a target temperature; measuring the heated focus ring for obtaining a thermal image of the heated focus ring; and determining a connection state between the focus ring and the heat transfer member on a basis of data obtained in the measuring.

According to still another embodiment of the present disclosure, there is provided a substrate processing device for processing a substrate, the device including: a chamber having a processing space therein and comprising an area formed of a transparent material; a substrate support unit configured to support the substrate in the processing space; a gas supply unit configured to supply gas into the processing space; a plasma generating unit for exciting the gas into a state of plasma in the processing space; the focus ring configured to focus the plasma onto the substrate, the focus ring comprising a heat transfer member provided on a lower surface thereof; and the inspection unit configured to inspect a connection state between the focus ring and the heat transfer member on a basis of a thermal image of the focus ring.

According to the present disclosure, through the inspection of the focus ring by using the infrared camera, even a minute thermal gradient in the focus ring can be checked.

In addition, according to the present disclosure, the connection state of the heat transfer member attached to the lower part of the focus ring is inspected on the basis of the thermal image of the focus ring, thereby identifying a focus ring in a poor adhesion state.

The effects of the present disclosure are not limited to the above-mentioned effects, and effects not mentioned will be clearly understood by those skilled in the art to which the present disclosure belongs from this specification and the accompanying drawings.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a top view illustrating an example of a focus ring that can be inspected by a focus ring inspection device of the present disclosure;

FIG. 2 is a sectional view schematically illustrating the focus ring inspection device according to an embodiment of the present disclosure;

FIG. 3 is a diagram illustrating a substrate processing device according to the embodiment of the present disclosure;

FIG. 4 is a diagram illustrating an example in which the focus ring inspection device according to the embodiment of the present disclosure is applied in FIG. 3;

FIG. 5 is a diagram illustrating a substrate processing device according to another embodiment of the present disclosure; and

FIG. 6 is a flowchart illustrating a focus ring inspection method according to the embodiment of the present disclosure.

### DETAILED DESCRIPTION OF THE INVENTION

Hereinafter, with reference to the accompanying drawings, embodiments of the present disclosure will be described in detail so that a person having ordinary knowledge in the technical field to which the present disclosure belongs can easily practice the embodiments. However, the present disclosure may be implemented in several different forms and is not limited to the embodiments described herein.

In describing the embodiments of the present disclosure, if it is determined that a specific description of a related known function or configuration may unnecessarily obscure the gist of the present disclosure, the specific description is omitted, and parts in which similar functions or operations are performed will use the same reference numerals throughout the drawings.

Since at least some of terms used in this specification are defined in consideration of functions in the present disclosure, the definition thereof may vary depending on users, operator intentions, and customs, etc. Therefore, the terms should be interpreted on the basis of contents throughout the specification.

In addition, in this specification, singular forms also include plural forms unless specifically stated otherwise in a phrase. In the specification, when it is said to include a certain component, this means that it may further include other components without excluding the other components unless otherwise stated. In addition, when a part is said to be connected (or combined) with another part, these are not only directly connected (or combined) with each other, but also may be indirectly connected (or combined) with each other through still another part.

Meanwhile, in the drawings, the size and shape of component, and the thickness of a line may be somewhat exaggerated for convenience of understanding.

The embodiments of the present disclosure are described with reference to schematic diagrams of ideal embodiments of the present disclosure. Accordingly, variations from the shape of the illustration, for example, variations in a manufacturing method and/or a tolerance, may be expected. Accordingly, the embodiments of the present disclosure are not described as being limited to specific shapes of areas described as illustrations, but include deviations in the shapes. The elements described in the drawings are entirely schematic and the shapes of the elements are not intended to describe the precise shapes of the elements, nor are intended to limit the scope of the present disclosure.

When an element or layer is referred to as being “on” or “above” another element or layer, this includes both a case in which the element or layer is directly on top of another element or layer as well as a case in which still another layer or element is interposed therebetween. On the other hand, when an element is referred to as being “directly on” or “directly above” another element or layer, it indicates that there is no intervening element or layer therebetween.

Spatially relative terms “below”, “beneath”, “lower”, “above”, and “upper”, etc. may be used to easily describe correlation between elements or components and other elements or components as illustrated in the drawings. The spatially relative terms should be understood as encompassing different directions of elements in use or operation thereof in addition to the directions shown in the drawings. For example, when flipping elements shown in the drawings, elements described as being “below” or “beneath” other elements may be placed “above” the other elements. Accordingly, the exemplary term “below” may include directions directed below and above. Elements may also be directed in other directions, and thus the spatially relative terms may be interpreted according to direction.

Although first and second, etc. are used to describe various elements, components and/or sections, it is needless to say that these elements, components and/or sections are not limited by these terms. These terms are only used to distinguish one element, component, or section from another element, component, or section. Accordingly, a first element, first component, or first section referred to below may also be a second element, second component, or second section within the technical spirit of the present disclosure.

Hereinafter, the embodiments of the present disclosure will be described in detail with reference to the accompanying drawings. In the description with reference to the accompanying drawings, the same or corresponding components regardless of reference numerals are given the same reference numerals, and redundant descriptions thereof are omitted.

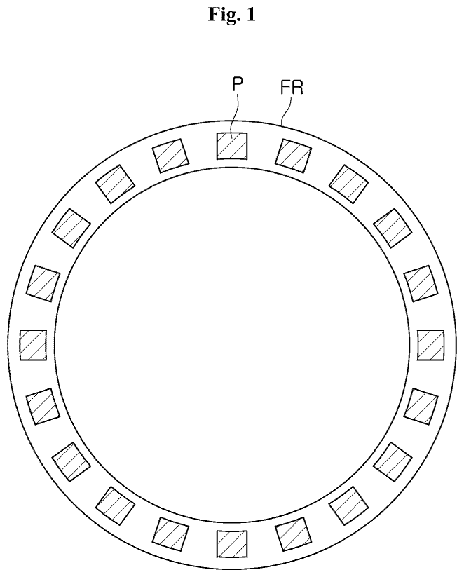

FIG. 1 is a top view schematically illustrating a focus ring FR according to one embodiment of the present disclosure.

The focus ring FR may be disposed on the edge area of a substrate W and a substrate support unit supporting the substrate W in a plasma processing device. The focus ring FR has a ring shape and is disposed along the periphery of the substrate support unit. An upper surface of the focus ring FR may be stepped so that an outer portion of the upper surface is higher than an inner portion thereof. The inner portion of the upper surface of the focus ring FR may be provided to surround the edge area of the substrate W seated on the substrate support unit. The focus ring FR may expand an electric field formation area so that the substrate W is positioned at the center of a plasma formation area. Accordingly, plasma is uniformly formed over the entire area of the substrate W, so that each area of the substrate W can be uniformly etched. The focus ring FR may include a heat transfer member P to improve heat transfer efficiency between the substrate support unit and the focus ring.

In general, the heat transfer member P may include one or more heat transfer members having shapes of pads or sheets and attached to the lower surface of the focus ring FR. The plurality of heat transfer members P may be attached at regular intervals on the lower surface of the focus ring FR having an annular shape. Accordingly, when the focus ring FR is mounted on a substrate processing device, the heat transfer member P is located under the focus ring FR and on the upper side of the substrate support unit, so the heat transfer member P may function to flexibly and efficiently transfer heat emitted or absorbed from the substrate support unit to the focus ring FR. For example, the heat transfer member P may be provided by being inserted into at least one groove formed in the lower surface of the focus ring FR. In this case, the heat transfer member P may be provided to have a size corresponding to the groove formed in the lower surface of the focus ring FR.

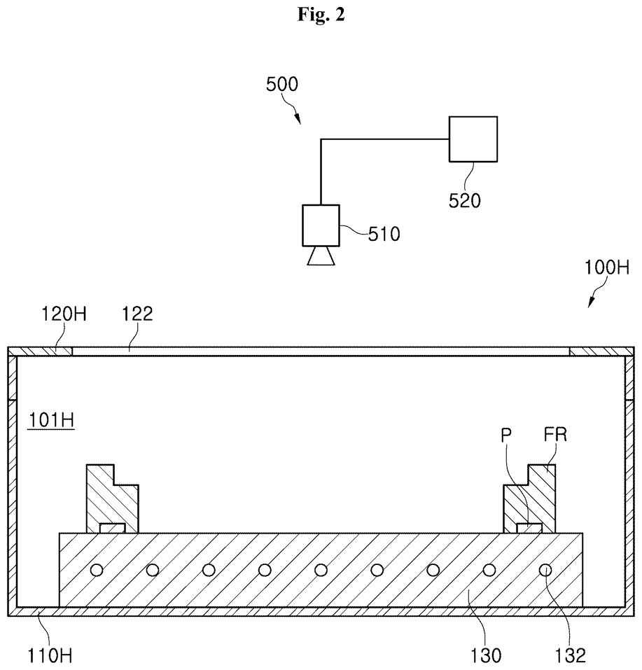

FIG. 2 is a sectional view schematically illustrating the structure of the focus ring inspection device according to the embodiment of the present disclosure.

The focus ring inspection device inspects the focus ring FR applied to a plasma device. Specifically, the focus ring inspection device may inspect the focus ring FR including the heat transfer member P so as to improve heat transfer efficiency between the focus ring and the substrate support unit on which the focus ring is seated. The focus ring inspection device may inspect a connection state between the focus ring FR and the heat transfer member P, that is, an attachment state therebetween.

Referring to FIG. 2, the focus ring inspection device may include a housing 100H, a hot plate 130, and an inspection unit 500.

The housing 100H has an inner space 101H formed therein. The inner space 101H is provided as a space for performing an inspection process for the focus ring FR. A predetermined area of one wall of walls defining the space of the housing 100H may be formed of a transparent material. For example, a predetermined area of the upper wall of the housing 100H may be formed of a transparent material.

The housing 100H may include a body 110H and a cover 120H. The body 110H is open at an upper surface thereof and has space formed therein. The cover 120H may be placed on the upper end of the body 110H and may seal the open upper surface of the body 110H. The sealed inside of the housing 100H may be maintained at pressure lower than normal pressure.

Although not shown in detail, an entrance may be formed on one side wall of the housing 100H. The entrance may be provided as a path through which the focus ring FR can move into and out of the housing 100H. The entrance may be opened and closed by an opening and closing member such as a door.

The upper wall of the cover 120 may include a transparent area 122 made of a transparent material. For example, the transparent area 122 may be a view port. The inspection unit 500 may obtain a thermal image of the focus ring FR through the transparent area 122.

The hot plate 130 supports the focus ring FR inside the inner space 101H of the housing 100H (i.e., an inspection space). The hot plate 130 may include heating members 132.

The hot plate 130 may be provided as a disc having a predetermined thickness and having a larger radius than the focus ring FR. A seating groove in which the focus ring FR is seated may be formed in an upper surface of the hot plate 130. According to the embodiment, the hot plate 130 is not provided with a structure for fixing the focus ring FR, and the focus ring FR may be heat treated while placed on the hot plate 130. When the focus ring FR is seated on the hot plate 130, the heat transfer member P may be disposed between the focus ring FR and the hot plate 130.

Each of the heating members 132 is provided inside the hot plate 130. For example, the heating member 132 may be provided as a heater, and the heater may be provided as a spiral coil. The heating members 132 may be installed at regular intervals inside the hot plate 130. The heating member 132 may be connected to an external power source (not shown) and may generate heat by resisting a current applied from the external power source. The generated heat is transferred through the heat transfer member P to the focus ring FR, and the focus ring FR may be heated to a predetermined temperature.

Meanwhile, the hot plate 130 may have a plurality of pin holes (not shown) formed therein, and each of the pin holes may be provided with a lift pin that moves in a vertical direction along the pin hole. A plurality of lift pins may be provided to load the focus ring FR to be inspected onto the hot plate 130 or to unload the focus ring FR placed on the hot plate 130.

The inspection unit 500 is provided above the housing 100H to inspect a connection state between the focus ring FR and the heat transfer member P. The inspection unit 500 may include a camera module 510 configured to photograph the focus ring FR, and an inspection part 520 configured to monitor the connection state between the focus ring FR and the heat transfer member P on the basis of an image of the focus ring FR photographed by the camera module 510.

The camera module 510 may be installed above the housing 100H to capture the focus ring FR through the transparent area 122. For example, the camera module 510 may include an infrared camera capable of obtaining the thermal image of an object. The camera module 510 may be provided as the infrared camera to photograph the focus ring FR. The camera module 510 provided as the infrared camera may obtain the thermal image of the focus ring FR by photographing the focus ring FR which is completely heat treated by the hot plate 130. For example, completely heat treated may mean that the focus ring FR has been heated for a predetermined time. The camera module 510 may transmit the obtained image to the inspection part 520.

Meanwhile, the camera module 510 is not limited to being located at a side above the housing 100H, but may be installed at various locations at which the thermal image of the focus ring FR can be obtained by capturing the focus ring FR. The location of the transparent area 122 may be changed according to the location of the camera module 510.

The inspection part 520 receives an image obtained by the camera module 510, and on the basis of the image, a connection state between the focus ring FR and the heat transfer member P may be determined. The inspection part 520 may determine a connection state between the focus ring FR and the heat transfer member P on the basis of a thermal image obtained by the camera module 510 provided as the infrared camera. For example, the inspection part 520 compares the thermal image of the focus ring FR received from the camera module 510 with a reference image, and may determine that the connection state between the focus ring FR and the heat transfer member P is abnormal when a comparison value exceeds a preset value. The reference image to be compared may be previously stored in the inspection part 520 as the thermal image of the focus ring FR in a normal state. For example, the inspection part 520 may be provided as a PC including a storage device. For example, the inspection part 520 may include a central processing unit (CPU) with a storage device such as a hard disk drive (HDD and a solid-state-drive (SSD).

Meanwhile, the inspection part 520 may determine a connection state between the focus ring FR and the heat transfer member P on the basis of the distribution uniformity of the thermal image of the focus ring FR obtained by the camera module 510. When the temperature distribution of the thermal image of the focus ring FR received from the camera module 510 is uniform over the entire area of the focus ring FR, the inspection part 520 may determine that there is no abnormality in the connection state between the focus ring FR and the heat transfer member P. That is, the inspection part 520 may determine that the connection state between the focus ring FR and the heat transfer member P is normal.

On the other hand, when the temperature distribution of the thermal image of the focus ring FR received from the camera module 510 is not uniform over the entire area of the focus ring FR, the inspection part 520 may determine that the connection state between the focus ring FR and the heat transfer member P is abnormal. That is, the inspection part 520 may determine that the connection state between the focus ring FR and the heat transfer member P is defective.

Accordingly, the inspection device according to the embodiment of the present disclosure, which is a separate device for inspecting the focus ring FR, may obtain the thermal image of the focus ring FR heated and may inspect a connection state between the focus ring FR and the heat transfer member P attached to the lower surface of the focus ring FR on the basis of the obtained thermal image of the focus ring FR. In addition, it is possible to check a minute temperature gradient (thermal gradient) inside the focus ring FR. An uneven temperature gradient in the focus ring FR, which may be caused by poor contact between the focus ring FR and the heat transfer member P, affects the etching rate of the substrate and the line width of the pattern formed on the substrate, and thus by using the inspection device of the present disclosure, poor contact between the focus ring FR and the heat transfer member P can be identified in advance to prevent the poor contact.

Meanwhile, the above-described separate device may be applied to the plasma processing device.

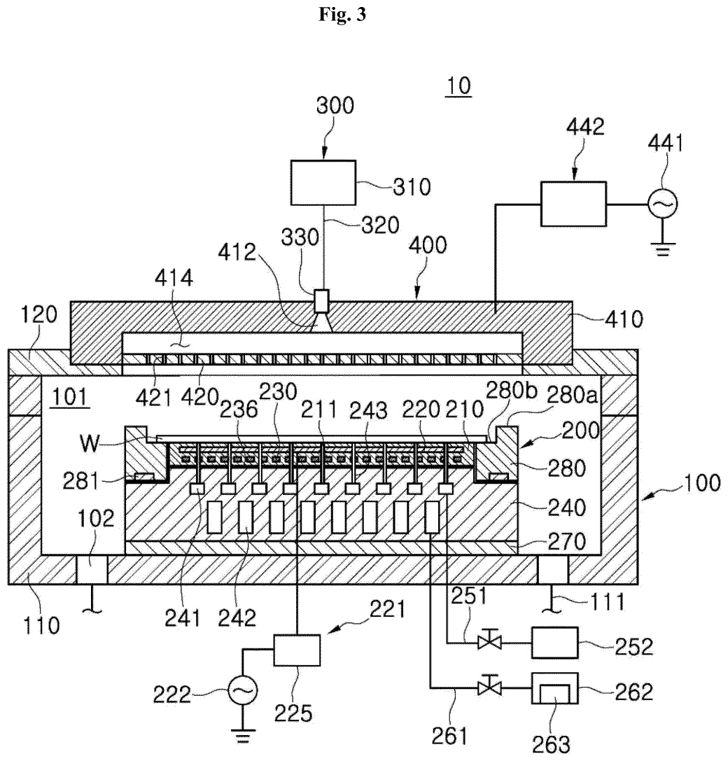

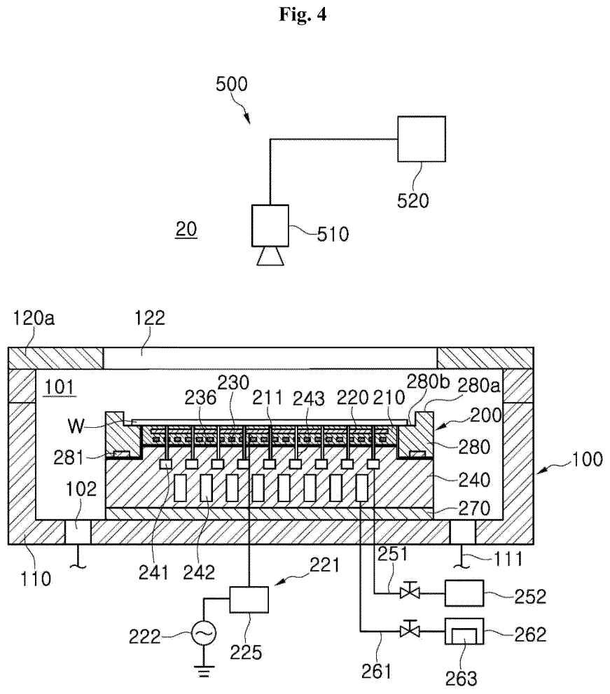

FIGS. 3 and 4 are sectional views illustrating the substrate processing device according to the embodiment of the present disclosure.

FIG. 3 is a diagram illustrating the state of the substrate processing device 10 according to the embodiment of the present disclosure when a substrate processing process is performed.

Referring to FIG. 3, the substrate processing device 10 performs processing on the substrate W by using plasma. For example, the substrate processing device 10 may perform an etching process on the substrate W. The substrate processing device 10 includes a chamber 100, the substrate support unit 200, a gas supply unit 300, and a plasma generating unit 400.

The chamber 100 has an inner space 101 formed therein. The inner space 101 may be provided as a space for performing plasma treatment on the substrate W. The plasma treatment of the substrate W includes an etching process.

The chamber 100 may include the body 100 and the cover 120. The body 110 is open in an upper surface thereof and has space formed therein, and the cover 120 is placed on the upper end of the body 110 and may seal the open upper surface of the body 110.

The chamber 100 may have a substrate introduction hole formed in one side wall thereof. The substrate introduction hole is provided as a path through which the substrate W can move into and out of the chamber 100. The substrate introduction hole may be opened and closed by an opening and closing member such as a door.

The chamber 100 has an exhaust hole 102 formed on a bottom surface thereof. The exhaust hole 102 is connected to an exhaust line 111, and reaction by-products generated in the process and gas remaining in the chamber 100 may be discharged through the exhaust line 111 to the outside. In addition, the inner space 101 of the chamber 100 may be decompressed to a predetermined pressure by an exhausting process.

The substrate support unit 200 is located inside the chamber 100. The substrate support unit 200 supports the substrate W. The substrate support unit 200 includes an electrostatic chuck that adsorbs and fixes the substrate W by using electrostatic force. The substrate support unit 200 includes a dielectric plate 210, a lower electrode 220, a heater 230, a support plate 240, and an insulation plate 270.

The dielectric plate 210 is located on the upper end part of the substrate support unit 200. The dielectric plate 210 is provided as a disc-shaped dielectric. The substrate W is placed on the upper surface of the dielectric plate 210. The upper surface of the dielectric plate 210 has a radius smaller than the radius of the substrate W. Accordingly, the edge area of the substrate W is located outside the dielectric plate 210. The dielectric plate 210 has a first supply flow path 211 formed therein. The first supply flow path 211 is formed from the upper surface of the dielectric plate 210 to the lower surface thereof. The first supply flow path 211 includes a plurality of first supply flow paths formed by being spaced apart from each other, and is provided as a path through which a heat transfer medium is supplied to the lower surface of the substrate W. A separate electrode for adsorbing the substrate W to the dielectric plate 210 may be installed in the dielectric plate 210. A direct current may be applied to the electrode. An electrostatic force is generated between the electrode and the substrate by the applied current, and the substrate W may be adsorbed to the dielectric plate 210 by the electrostatic force.

The lower electrode 220 is connected to a lower power supply part 221. The lower power supply part 221 supplies power to the lower electrode 220. The lower power supply part 221 includes a lower RF power source 222 and a lower impedance matching part 225. The lower RF power source 222 may include a plurality of lower RF power sources, or may selectively include only one lower RF power source. The lower RF power source 222 mainly controls ion bombardment energy. The lower impedance matching part 225 is electrically connected to the lower RF power source 222 and applies matching frequency powers of different sizes to the lower electrode 220.

The heater 230 is electrically connected to an external power source (not shown). The heater 230 generates heat by resisting a current applied from the external power source. The generated heat is transferred through the dielectric plate 210 to the substrate W. The substrate W is maintained at a predetermined temperature by the heat generated by the heater 230. The heater 230 includes a spiral coil. The heater 230 may be installed in the dielectric plate 210 at regular intervals.

The support plate 240 is positioned under the dielectric plate 210. The lower surface of the dielectric plate 210 and the upper surface of the support plate 240 may be bonded to each other by an adhesive 236. The support plate 240 may be made of aluminum. The upper surface the support plate 240 may be stepped so that the center area of the upper surface is located higher than an edge area thereof. A central area of the upper surface of the support plate 240 has an area corresponding to the lower surface of the dielectric plate 210 and is bonded to the lower surface of the dielectric plate 210. The support plate 240 includes a first circulation flow path 241, a second circulation flow path 242, and a second supply flow path 243.

The first circulation flow path 241 is provided as a path through which a heat transfer medium circulates. The first circulation flow path 241 may be formed in a spiral shape inside the support plate 240. Alternatively, the first circulation flow path 241 may include ring-shaped first circulation flow paths having different radii so that the first circulation flow paths are arranged to have the same center. Each of the first circulation flow paths 241 may communicate with each other. The first circulation flow paths 241 are formed at the same height.

The second circulation flow path 242 serves as a passage through which a cooling fluid circulates. The second circulation flow path 242 may be formed in a spiral shape inside the support plate 240. Alternatively, the second circulation flow path 242 may include ring-shaped second circulation flow paths having different radii so that the second circulation flow paths are arranged to have the same center. Each of the second circulation flow path 242 may communicate with each other. The second circulation flow path 242 may have a larger cross-sectional area than the first circulation flow path 241. The second circulation flow paths 242 are formed at the same height. The second circulation flow path 242 may be located under the first circulation flow path 241.

The second supply flow path 243 extends upward from the first circulation flow path 241 and is formed up to the upper surface of the support plate 240. The second supply flow path 243 includes second supply flow paths of a number corresponding to the first supply flow paths 211, and connects the first circulation flow path 241 with the first supply flow path 211.

The first circulation flow path 241 is connected to a heat transfer medium storage part 252 through a heat transfer medium supply line 251. The heat transfer medium storage part 252 stores a heat transfer medium. The heat transfer medium includes an inert gas. According to the embodiment, the heat transfer medium includes a helium (He) gas. The helium gas is supplied to the first circulation flow path 241 through the heat transfer medium supply line 251, and is supplied through the second supply flow path 243 and the first supply flow path 211 sequentially to the lower surface of the substrate W. The helium gas serves as a medium through which heat transferred from plasma to the substrate W is transferred to the substrate support unit 200. Ion particles contained in the plasma are attracted to electric force formed in the substrate support unit 200 and move to the substrate support unit 200, and collide with the substrate W in the process of moving to perform an etching process. While the ion particles collide with the substrate W, heat is generated in the substrate W. The heat generated from the substrate W is transferred to the substrate support unit 200 through a helium gas supplied to space between the lower surface of the substrate W and the upper surface of the dielectric plate 210. Accordingly, the substrate W can be maintained at a preset temperature.

The second circulation flow path 242 is connected to a cooling fluid storage part 262 through a cooling fluid supply line 261. The cooling fluid storage part 262 stores a cooling fluid. A cooler 263 may be provided in the cooling fluid storage part 262. The cooler 263 cools a cooling fluid to a predetermined temperature. Alternatively, the cooler 263 may be installed in the cooling fluid supply line 261. A cooling fluid supplied to the second circulation flow path 242 through the cooling fluid supply line 261 circulates along the second circulation flow path 242 and cools the support plate 240. Due to the cooling of the support plate 240, the dielectric plate 210 and the substrate W are together cooled to maintain the substrate W at a predetermined temperature.

The insulation plate 270 is provided on the lower side of the support plate 240. The insulation plate 270 is provided to have a size corresponding to the support plate 240. The insulation plate 270 is located between the support plate 240 and the bottom surface of the chamber 100. The insulation plate 270 is formed of an insulating material and electrically insulates the support plate 240 from the chamber 100.

The focus ring 280 is disposed in the edge area of the substrate support unit 200. The focus ring 280 has a ring shape and is disposed along the circumference of the dielectric plate 210. The upper surface of the focus ring 280 may be stepped so that an outer portion 280a of the upper surface is higher than an inner portion 280b thereof. The inner portion 280b of the upper surface of the focus ring 280 is positioned at the same height as the upper surface of the dielectric plate 210. The inner portion 280b of the upper surface of the focus ring 280 supports an edge area of the substrate W positioned on the outer side of the dielectric plate 210. The outer portion 280a of the focus ring 280 is provided to surround the edge area of the substrate W. The focus ring 280 expands an electric field formation area so that the substrate W is located at the center of an area in which plasma is formed. Accordingly, plasma is uniformly formed over the entire area of the substrate W, so that each area of the substrate W can be uniformly etched. A thermally conductive pad may be positioned on the lower part of the focus ring.

The gas supply unit 300 supplies process gas to the chamber 100. The gas supply unit 300 includes a gas storage part 310, a gas supply line 320, and a gas introduction port 330. The gas supply line 320 connects the gas storage part 310 with the gas introduction port 330, and supplies process gas stored in the gas storage part 310 to the gas introduction port 330. The gas introduction port 330 is connected to a gas supply hole 412 formed in an upper electrode 410.

The plasma generating unit 400 excites process gas staying inside the chamber 100. The plasma generating unit 400 includes the upper electrode 410, a distribution plate 420, and an upper power supply part.

The upper electrode 410 is located above the substrate support unit 200. The upper electrode 410 is provided in a disk shape and may have the gas supply hole 412 formed in a central area of the upper electrode 410. The gas supply hole 412 is connected to the gas introduction port 330 and supplies process gas to buffer space 414.

The buffer space 414 may be provided as space in which gas supplied through the gas supply hole 412 temporarily stays before being supplied into the chamber 100.

The distribution plate 420 is located under the buffer space 414. The distribution plate 420 is provided in a disk shape. The distribution plate 420 may have distribution holes 421. The distribution holes 421 are formed from the upper surface of the distribution plate 420 to the lower surface thereof. Process gas staying in the buffer space 414 may be uniformly supplied into the chamber 100 through the distribution holes 421.

The upper power supply part applies RF power to the upper electrode 410. The upper power supply part includes an upper RF power 441 and an upper impedance matching part 442.

FIG. 4 is a sectional view illustrating a state 20 in which the focus ring is inspected by the substrate processing device according to the embodiment of the present disclosure. Referring to FIG. 4, when inspecting the focus ring 280, the substrate processing device 10 further includes the inspection unit 500.

When the inspection of the focus ring 280 seated on the substrate support unit 200 is performed, a focus ring inspection cover 120a may be provided on the upper end of the body 110. While the cover 120 of FIG. 3 is connected with the gas supply unit 300 and the plasma generating unit 400, the focus ring inspection cover 120a may not be connected with the gas supply unit 300 and the plasma generating unit 400. The focus ring inspection cover 120a seals the open upper surface of the body 110. Accordingly, in this case, the upper wall of the chamber 100 is the upper wall of the focus ring inspection cover 120a. The body 110 and the cover 120a define the inspection space of the focus ring. The upper wall of the cover 120a may include the transparent area 122 made of a transparent material. For example, the transparent area 122 may be a view port. The inspection unit 500 may obtain the thermal image of the focus ring 280 through the transparent area 122.

The inspection unit 500 may inspect a connection state between the focus ring 280 and the heat transfer member 281. The inspection unit 500 may include the camera module 510 configured to photograph the focus ring 280, and the inspection part 520 configured to monitor the connection state between the focus ring 280 and the heat transfer member 281 on the basis of an image of the focus ring photographed by the camera module 510. The inspection unit 500 inspects the connection state between the focus ring 280 and the heat transfer member 281 on the basis of the thermal image of the focus ring 280.

The camera module 510 may be installed above the chamber 100 to photograph the focus ring 280 through the transparent area 122. For example, the camera module 510 may include an infrared camera capable of obtaining the thermal image of an object. The camera module 510 is provided as the infrared camera and can capture the focus ring 280. The camera module 510 provided as the infrared camera may obtain the thermal image of the focus ring 280 by photographing the focus ring 280 which is completely heat treated by the hot plate 130. The camera module 510 may transmit the obtained image to the inspection part 520.

Meanwhile, the camera module 510 is not limited to being located at a side above the chamber 100, but may be installed at various locations at which the thermal image of the focus ring 280 can be obtained by capturing the focus ring 280. The location of the transparent area 122 may be changed according to the location of the camera module 510.

The inspection part 520 receives the image obtained by the camera module 510, and may determine the connection state between the focus ring 280 and the heat transfer member 281 on the basis of the image. The inspection part 520 may determine the connection state between the focus ring 280 and the heat transfer member 281 on the basis of the thermal image obtained by the camera module 510 provided as the infrared camera. For example, the inspection part 520 compares the thermal image of the focus ring 280 received from the camera module 510 with a reference image, and may determine that a connection state between the focus ring 280 and the heat transfer member 281 is abnormal when a comparison value exceeds a preset value. The reference image to be compared may be previously stored in the inspection part 520 as the thermal image of the focus ring 280 in a normal state.

As another example, the inspection part 520 may determine a connection state between the focus ring 280 and the heat transfer member 281 on the basis of the distribution uniformity of the thermal image of the focus ring 280 obtained by the camera module 510 When the temperature distribution of the thermal image of the focus ring 280 received from the camera module 510 is uniform over the entire area of the focus ring 280, the inspection part 520 may determine that there is no abnormality in the connection state between the focus ring 280 and the heat transfer member 281. That is, the inspection part 520 may determine that the connection state between the focus ring 280 and the heat transfer member 281 is normal.

On the other hand, when the temperature distribution of the thermal image of the focus ring FR received from the camera module 510 is not uniform over the entire area of the focus ring FR, the inspection part 520 may determine that a connection state between the focus ring FR and the heat transfer member P is abnormal. That is, the inspection part 520 may determine that the connection state between the focus ring FR [symbol] the heat transfer member P is defective.

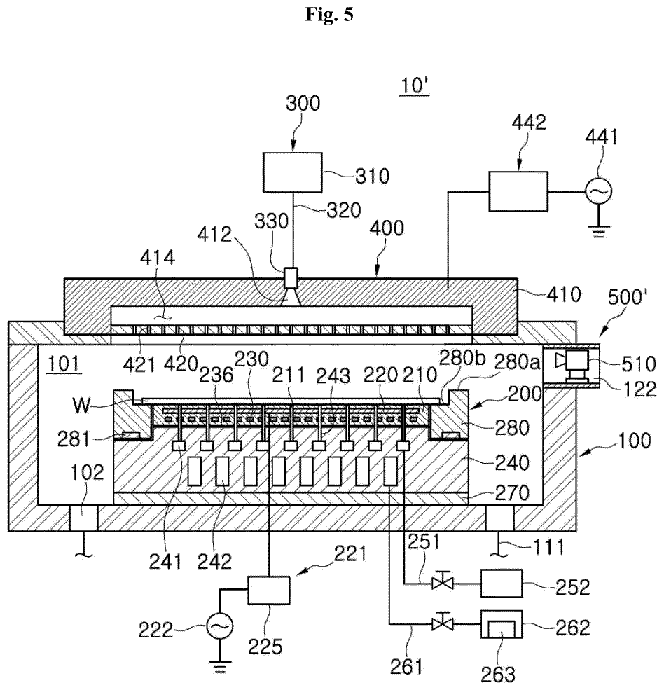

FIG. 5 is a sectional view illustrating a substrate processing device according to another embodiment of the present disclosure.

Since the configuration of the substrate processing device 10′ illustrated in FIG. 5 are the same as the configuration of the substrate processing device 10 illustrated in FIG. 3 except for the positions of the transparent area 122 and the camera module 510, description of the same configuration will be omitted. In addition, the chamber of the substrate processing device 10′ may not be divided into the body and the cover.

Referring to FIG. 5, the substrate processing device 10′ according to another embodiment of the present disclosure includes a chamber 100, a substrate support unit 200, a gas supply unit 300, a plasma generating unit 400, and an inspection unit 500′.

The chamber 100 includes a transparent area 122 formed of a transparent material provided on one side wall, and the inspection unit 500′ may obtain the thermal image of a focus ring 280 through the transparent area 122. For example, the camera module 510 of the inspection unit 500′ may be disposed inside the transparent area 122. Unlike the illustration of FIG. 5, the camera module 510 of the inspection unit 500′ may be installed outside the transparent area 122. That is, the camera module 510 may be installed on one side portion of the chamber 100 in which the transparent area 122 is formed and may photograph the focus ring 280 through the transparent area 122. For example, the transparent area 122 may be a view port.

Although not shown in detail, a light path forming member for forming a light path of the camera module 510 may be provided in the inner space 101 of the chamber 100 so that the camera module 510 provided on a side portion instead of a side above the substrate support unit 200 can photograph the entire area of the focus ring 280. For example, the light path forming member may be provided as a reflective member such as a mirror.

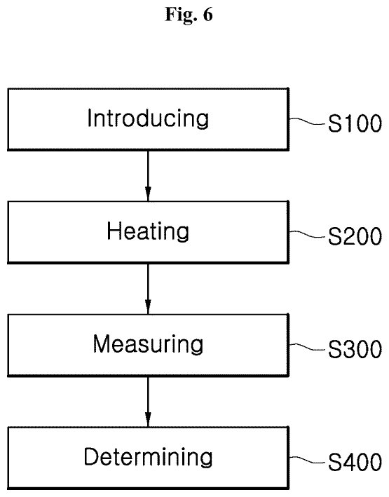

FIG. 6 is a flowchart illustrating a focus ring inspection method according to the embodiment of the present disclosure. The focus ring inspection method according to the embodiment of the present disclosure may be performed by one of devices illustrated in FIGS. 2, 4, and 5 described above.

The focus ring inspection method according to the embodiment of the present disclosure may be performed as a preliminary step prior to mounting the focus ring on the substrate processing device. Alternatively, the focus ring inspection method may be performed with the focus ring mounted on the substrate processing device.

The focus ring inspection method according to the embodiment of the present disclosure may include introducing at S100, heating S200, measuring at S300, and determining at S400.

The introducing at S100, which is a step of introducing an object to be inspected into the inspection space, is a step of introducing the focus ring having a heat transfer pad attached thereto into the inspection space. The introducing at S100 may be performed by a transfer robot that transports the focus ring while the focus ring is supported.

The heating at S200, which is a step of heat treating an object to be inspected, is a step of heating the focus ring, to which the heat transfer pad is attached, to a target temperature by the hot plate 130 or the substrate support unit 200. In the heating at S200, heating of the focus ring may be performed by transferring heat from the hot plate 130 or the substrate support unit 200 through the heat transfer member attached to the lower surface of the focus ring.

In the measuring at S300, which is a step of obtaining the thermal image of the focus ring heated by the heating at S200, the heat distribution of the heated focus ring may be measured. The measuring at S300 is performed by the camera module 510 provided for photographing the thermal image of the focus ring, and the camera module 510 may be an infrared camera provided on a side above or a portion beside the focus ring.

The determining at S400 is a step of determining a connection state between the focus ring and the heat transfer member on the basis of data obtained in the measuring at S300. Specifically, in the determining at S400, the connection state between the focus ring and the heat transfer member may be determined on the basis of an image obtained by the camera module 510. That is, the determining at S400 may be performed on the basis of the thermal image of the focus ring measured in the measuring at S300.

For example, the determining at S400 may include comparing the thermal image of the focus ring, which is obtained by the infrared camera photographing the focus ring, with a reference image. When a comparison value exceeds a preset value, it may be determined that the connection state between the focus ring FR and the heat transfer member P is abnormal. The reference image to be compared may be previously stored in the inspection part 520 as the thermal image of the focus ring FR in a normal state.

For another example, the determining at S400 may be the step of determining the connection state between the focus ring and the heat transfer member on the basis of the distribution uniformity of the thermal image of the focus ring obtained in the measuring at S300. For example, when the temperature distribution (heat distribution) of the thermal image of the focus ring obtained in the measuring at S300 is uniform over the entire area of the focus ring, it may be determined that there is no abnormality in the connection state between the focus ring and the heat transfer member in the determining at S400. On the other hand, when the temperature distribution (heat distribution) of the thermal image of the focus ring obtained in the measuring at S300 is not uniform over the entire area of the focus ring, it may be determined that there is abnormality in the connection state between the focus ring and the heat transfer member in the determining at S400.

As described above, in the device and method of the present disclosure, the thermal image of the focus ring to which the heat transfer member is attached is obtained, and on the basis of the thermal image, an adhesion state between the focus ring and the heat transfer member can be determined. Accordingly, even a minute thermal gradient in the focus ring can be checked, and the focus ring in which the heat transfer member has a poor adhesion state is identified in advance so that process defects due to an abnormal temperature gradient of the focus ring can be prevented, thereby improving productivity. In addition, the focus ring inspection device of the present disclosure can be applied as a separate device for inspecting the focus ring, and further, can be applied to the inspection of the focus ring already used for plasma processing by being applied to a plasma processing device, thereby providing a more efficient focus ring inspection technology.

The above description is only an exemplary description of the technical idea of the present disclosure, and the present disclosure may be variously modified and varied to a person having ordinary knowledge in the technical field to which the present disclosure belongs without departing from the essential characteristics of the present disclosure. Accordingly, the embodiments described in the present disclosure are not intended to limit the technical idea of the present disclosure, but to explain, and the technical idea of the present disclosure is not limited by these embodiments. The scope of protection of the present disclosure should be interpreted according to the scope of the claims below, and all technical ideas within the scope equivalent thereto should be construed as being included in the scope of claims of the present disclosure.

What is claimed is:

1. An inspection device for inspecting a focus ring comprising a heat transfer member, the inspection device comprising:
a housing having inspection space to accommodate the focus ring, with a predetermined area of an upper wall of the housing being formed of a transparent material;
a hot plate provided in the inspection space and configured to heat the focus ring while the hot plate supports the focus ring; and
an inspection unit configured to inspect a connection state between the focus ring and the heat transfer member by obtaining a thermal image of the focus ring after the focus ring is completely heat treated.

2. The inspection device of claim 1,
wherein the inspection unit comprises:
an infrared camera configured to photograph the focus ring; and
an inspection part configured to monitor the connection state between the focus ring and the heat transfer member on a basis of an image of the focus ring photographed by the infrared camera.

3. The inspection device of claim 2,
wherein the infrared camera obtains a thermal image of an inside of the focus ring which is completely heat treated.

4. The inspection device of claim 3,
wherein the inspection part determines the connection state between the focus ring and the heat transfer member on a basis of the thermal image obtained by the infrared camera.

5. The inspection device of claim 1,
wherein the heat transfer member is disposed between the focus ring and the hot plate and comprises one or more heat transfer members, each of the heat transfer members having a shape of a pad or sheet.

6. The inspection device of claim 5,
wherein when the focus ring is heat treated by the hot plate, heat of the hot plate is transferred through the heat transfer member to the focus ring.

7. The inspection device of claim 5,
wherein at least one groove is formed in a lower surface of the focus ring, and the heat transfer member is inserted into the groove.

8. An inspection method comprising:
introducing a focus ring having a heat transfer member attached thereto into inspection space;
heating the focus ring to a target temperature;
measuring the heated focus ring for obtaining a thermal image of the heated focus ring; and
determining a connection state between the focus ring and the heat transfer member on a basis of data obtained in the measuring.

9. The inspection method of claim 8,
wherein the heating is performed by heat transferred to the focus ring through the heat transfer member.

10. The inspection method of claim 9,
wherein the measuring is performed by an infrared camera provided for photographing the focus ring.

11. The inspection method of claim 10,
wherein in the determining, the thermal image obtained by the infrared camera is compared with a reference image, and on a basis of a comparison value, the connection state between the focus ring and the heat transfer member is determined.

12. The inspection method of claim 11,
wherein the determining is performed before the focus ring is mounted to a substrate processing device.

13. The inspection method of claim 11,
wherein the determining is performed after the focus ring is mounted to a substrate processing device.

14. The inspection method of claim 10,
wherein in the determining, the connection state between the focus ring and the heat transfer member is determined on a basis of distribution uniformity of the thermal image of the focus ring obtained in the measuring.

15. The inspection method of claim 14,
wherein in the determining, when distribution of the thermal image of the focus ring obtained in the measuring is uniform over an entire area of the focus ring, it is determined that the connection state between the focus ring and the heat transfer member is normal.

16. A substrate processing device for processing a substrate, the device comprising:
a chamber having a processing space therein and comprising an area formed of a transparent material;
a substrate support unit configured to support the substrate in the processing space;
a gas supply unit configured to supply gas into the processing space;
a plasma generating unit for exciting the gas into a state of plasma in the processing space;
a focus ring configured to focus the plasma onto the substrate, the focus ring comprising a heat transfer member provided on a lower surface thereof; and
an inspection unit configured to inspect a connection state between the focus ring and the heat transfer member on a basis of a thermal image of the focus ring.

17. The device of claim 16,
wherein the inspection unit comprises:
an infrared camera configured to photograph the focus ring through the area formed of a transparent material; and
an inspection part configured to monitor the connection state between the focus ring and the heat transfer member on a basis of an image of the focus ring photographed by the infrared camera.

18. The device of claim 17,
wherein the infrared camera obtains a thermal image of an inside of the focus ring.

19. The device of claim 18,
wherein the inspection part determines the connection state between the focus ring and the heat transfer member on the basis of the thermal image obtained by the infrared camera.

20. The device of claim 19,
wherein the inspection part determines the connection state between the focus ring and the heat transfer member on a basis of uniformity of the thermal image of the focus ring obtained by the infrared camera.
